(19) United States
(12) Patent Application Publication
(10) Pub. No.: US 2016/0024658 A1
(43) Pub. Date: Jan. 28, 2016

(54) FILM-FORMING DEVICE

(71) Applicants: Kentaro SHINODA, Nagoya-shi, Aichi-ken (JP); Kazunari TAKI, Nagoya-shi, Aichi-ken (JP); Hideki KANADA, Toyohashi-shi, Aichi-ken (JP); Hiroyuki KOUSAKA, Nagoya-shi, Aichi-ken (JP); Yasuyuki TAKAOKA, Nagoya-shi, Aichi-ken (JP)

(72) Inventors: Kentaro SHINODA, Nagoya-shi, Aichi-ken (JP); Kazunari TAKI, Nagoya-shi, Aichi-ken (JP); Hideki KANADA, Toyohashi-shi, Aichi-ken (JP); Hiroyuki KOUSAKA, Nagoya-shi, Aichi-ken (JP); Yasuyuki TAKAOKA, Nagoya-shi, Aichi-ken (JP)

(73) Assignee: NATIONAL UNIVERSITY CORPORATION NAGOYA UNIVERSITY, Nagoya-shi, Aichi (JP)

(21) Appl. No.: 14/779,806

(22) PCT Filed: Mar. 17, 2014
(86) PCT No.: PCT/JP2014/057087

§ 371 Date: Sep. 24, 2015

(30) Foreign Application Priority Data
Mar. 28, 2013 (JP) 2013069713

(51) Int. Cl. C23C 16/511; C23C 16/458

(52) U.S. Cl. CPC C23C 16/511; C23C 16/458

(57) ABSTRACT

A film-forming device includes: a microwave supplying unit, which supplies microwaves for generating plasma along a treatment surface of a central conductor comprising at least a conductive workpiece material; a negative voltage applying unit, which applies to the workpiece material a negative bias voltage for expanding a sheath layer along the treatment surface of the workpiece material; a microwave transmitting window, which make the microwave, which is supplied by the microwave supplying unit, propagate to the expanded sheath layer through a microwave transmitting surface thereof, and a surrounding wall, which surrounds the microwave transmitting surface of the microwave transmitting window and protrudes beyond the microwave transmitting surface in a propagation direction in which the microwaves propagate.

### TECHNICAL FIELD

The present invention relates to a film-forming device for forming a film on a surface of a conductive workpiece material such as steel material by using plasma.

### BACKGROUND ART

In the background art, a variety of film-forming devices for forming a film on a surface of a conductive workpiece material such as steel material by using plasma have been proposed. For example, Japanese Patent Application Publication No. 2004-47207A discloses a technology of forming a diamond-like carbon (DLC) film on the surface of the workpiece material.

According to the technology disclosed in Japanese Patent Application Publication No. 2004-47207A, a plasma generating device supplies microwaves towards a workpiece material in a treatment chamber through a quartz window, which is a microwave transmitting window, thereby generating plasma in a peripheral region of a microwave transmitting surface, which is inside the quartz window. Subsequently, the plasma generating device applies a negative bias voltage to the workpiece material during the supply of the microwaves. As a result, a sheath layer is generated along a surface of the workpiece material, the generated sheath layer expands along the surface of the workpiece material, i.e., from the surface towards an outer side. At the same time, the supplied microwaves propagate along the sheath layer, as surface waves with a high energy density and the plasma extends. As a result, a source gas is plasma-excited by the surface waves and becomes high density plasma, so that a DLC film is formed on the surface of the workpiece material.

### SUMMARY OF THE PRESENT INVENTION

### Problems to be Solved

However, according to the technology disclosed in Japanese Patent Application Publication No. 2004-47207A, a film is also attached to the microwave transmitting surface of the quartz window, during the film formation on the surface of the workpiece material. The film attached to the microwave transmitting surface is charged by the plasma and causes an arcing, for example. As a result, the plasma discharge is unstable, so that film characteristics of the film formed on the surface of the workpiece material may be non-uniform. In order to reduce the non-uniformity of the film characteristics, it is necessary to frequently replace the quartz window, for example, so that the productivity is lowered.

It is therefore an object of the present invention to provide a film-forming device capable of reducing attachment of a film component to a microwave transmitting surface of a microwave transmitting window, thereby improving the productivity.

### Means for Solving the Problems

In order to achieve the above object, a film-forming device of the present invention includes: a microwave supplying unit, which supplies microwaves for generating plasma along a treatment surface of a central conductor comprising at least a conductive workpiece material; a negative voltage applying unit, which applies to the workpiece material a negative bias voltage for expanding a sheath layer along the treatment surface of the workpiece material; a microwave transmitting window, which make the microwave, which is supplied by the microwave supplying unit, propagate to the expanded sheath layer through a microwave transmitting surface thereof, and a surrounding wall, which surrounds the microwave transmitting surface of the microwave transmitting window and protrudes beyond the microwave transmitting surface in a propagation direction in which the microwaves propagate.

According to the film-forming device, the microwave transmitting surface, which makes the microwaves propagate to the expanded sheath layer is surrounded by the surrounding wall protruding in the propagation direction of the microwaves. For this reason, a surrounding space surrounding the expanded sheath layer and closed at a side facing the microwave transmitting surface is formed at an inner side of the surrounding wall. Thereby, after a film is formed on the central conductor by the source gas supplied into the surrounding space, it is possible to reduce the additional supply of the source gas into the surrounding space. Therefore, it is possible to reduce an amount of a film component to be attached to the microwave transmitting surface, thereby reducing the arcing occurrence. As a result, it is possible to prolong the lifetime of the microwave transmitting window, thereby improving the productivity.

In the film-forming device of the present invention, a distance from an inner peripheral surface of the surrounding wall to an outer peripheral surface of the central conductor arranged at an inner side of the surrounding wall may be formed to be shorter than a height from the microwave transmitting surface to a tip of the surrounding wall opposite to the microwave transmitting surface.

According to the film-forming device, the distance from the inner peripheral surface of the surrounding wall to the outer peripheral surface of the central conductor arranged at the inner side of the surrounding wall is formed to be shorter than the height from the microwave transmitting surface to the tip of the surrounding wall opposite to the microwave transmitting surface. Thereby, the surrounding space surrounding the central conductor formed at the inner side of the surrounding wall can be formed to be narrow in a sheath thickness direction of a sheath layer and to be high in the propagation direction of the microwaves. Therefore, after a film is formed on the central conductor by the source gas supplied into the surrounding space, it is possible to further reduce the additional supply of the source gas into the surrounding space, so that it is possible to further reduce an attachment amount of the film component to the microwave transmitting surface.

In the film-forming device of the present invention, the distance may be formed to be 2 mm or less, and the height may be formed to be 30 mm or greater.

According to the film-forming device, the distance from the inner peripheral surface of the surrounding wall to the outer peripheral surface of the central conductor is formed to be 2 mm or less, and the height from the microwave transmitting surface to the tip of the surrounding wall, which is opposite to the microwave transmitting surface, is formed to be 30 mm or greater. Thereby, after a film is formed on the central conductor by the source gas supplied into the surrounding space, it is possible to further reduce the additional supply of the source gas into the surrounding space.

In the film-forming device of the present invention, a thickness of a tip portion of the surrounding wall, which is opposite to the microwave transmitting surface, in a direction perpendicular to the propagation direction may be formed to be 4 mm or greater.

According to the film-forming device, the thickness of the tip portion of the surrounding wall, which is opposite to the microwave transmitting surface, in the direction perpendicular to the propagation direction of the microwaves is formed to be 4 mm or greater. Thereby, it is possible to reduce the arcing occurrence due to the electric field concentration on the tip portion of the surrounding wall opposite to the microwave transmitting surface. Therefore, it is possible to stabilize the plasma discharge, thereby forming a desired film having uniform film characteristics on the surface of the workpiece material.

In the film-forming device of the present invention, a tip portion of the surrounding wall opposite to the microwave transmitting surface may be roundly chamfered.

According to the film-forming device, the tip portion of the surrounding wall, which is opposite to the microwave transmitting surface, is roundly chamfered, so that it is possible to reduce the arcing occurrence due to the electric field concentration on the tip portion of the surrounding wall opposite to the microwave transmitting surface. Therefore, it is possible to stabilize the plasma discharge, thereby further securely forming a desired film having uniform film characteristics on the surface of the workpiece material.

In the film-forming device of the present invention, a tip portion of the surrounding wall opposite to the microwave transmitting surface may be angled-chamfered.

According to the film-forming device, the tip portion of the surrounding wall, which is opposite to the microwave transmitting surface, is angled-chamfered, so that it is possible to reduce the arcing occurrence due to the electric field concentration on the tip portion of the surrounding wall opposite to the microwave transmitting surface. Therefore, it is possible to stabilize the plasma discharge, thereby further securely forming a desired film having uniform film characteristics on the surface of the workpiece material.

The film-forming device of the present invention may further include a fixing member, which fixes the surrounding wall and the microwave transmitting window to a treatment chamber, and an attachment member, which attaches the fixing member to the treatment chamber. The attachment member may be arranged at an outer side of the surrounding wall and may be provided not to protrude from a surface of the fixing member.

According to the film-forming device, the attachment member to attach the support member, which is configured to support the surrounding wall and the microwave transmitting window to the treatment chamber, to the treatment chamber is arranged at the outer side of the surrounding wall, and is provided not to protrude from the surface of the fixing member. Thereby, it is possible to reduce the arcing occurrence due to the electric field concentration on the attachment member. Therefore, it is possible to stabilize the plasma discharge, thereby further securely forming a desired film having uniform film characteristics on the surface of the workpiece material.

In the film-forming device of the present invention, the inner peripheral surface of the surrounding wall may be made of metal.

According to the film-forming device, the inner peripheral surface of the surrounding wall is made of metal. A negative bias voltage is not applied to the inner peripheral surface. For this reason, it is possible to concentrate the plasma on the central conductor arranged at the inner side of the surrounding wall, so that it is possible to reduce the arcing occurrence due to the electric field concentration. Therefore, it is possible to stabilize the plasma discharge, thereby further securely forming a desired film having uniform film characteristics on the surface of the workpiece material.

In the film-forming device of the present invention, a tip portion of the surrounding wall opposite to the microwave transmitting surface may be electrically connected to a treatment chamber having the microwave transmitting window.

According to the film-forming device, since the tip portion of the surrounding wall, which is opposite to the microwave transmitting surface, is electrically connected to a treatment chamber having the microwave transmitting window, it is possible to reduce the arcing occurrence due to the electric field concentration. Therefore, it is possible to stabilize the plasma discharge, thereby further securely forming a desired film having uniform film characteristics on the surface of the workpiece material.

### BRIEF DESCRIPTION OF THE DRAWINGS

FIG. 1 is a view to illustrate a schematic configuration of a film-forming device according to an illustrative embodiment.

FIG. 2 is a view to illustrate a surrounding space that is to be formed by a workpiece material and a surrounding wall.

FIG. 3 is a view to illustrate the surrounding space that is to be formed by the workpiece material and the surrounding wall.

FIG. 4 is a schematic view of a waveform of a microwave pulse and a waveform of a negative bias voltage pulse.

FIG. 5 is a view showing an example where a tip portion of the surrounding wall is roundly chamfered.

FIG. 6 is a view showing an example where a tip portion of the surrounding wall is angle-chamfered.

FIG. 7 is a view showing an example of film formation conditions.

FIG. 8 is a view showing an example of a test result showing the measured number of continuous usable times of the microwave transmitting window.

FIG. 9 is an enlarged view of an X1 part of FIG. 8.

FIG. 10 is a view to illustrate a height of a head of a fixing screw.

FIG. 11 is a view showing an example of a test result showing the number of times of arcing occurrence during film formation.

### DESCRIPTION OF EMBODIMENTS

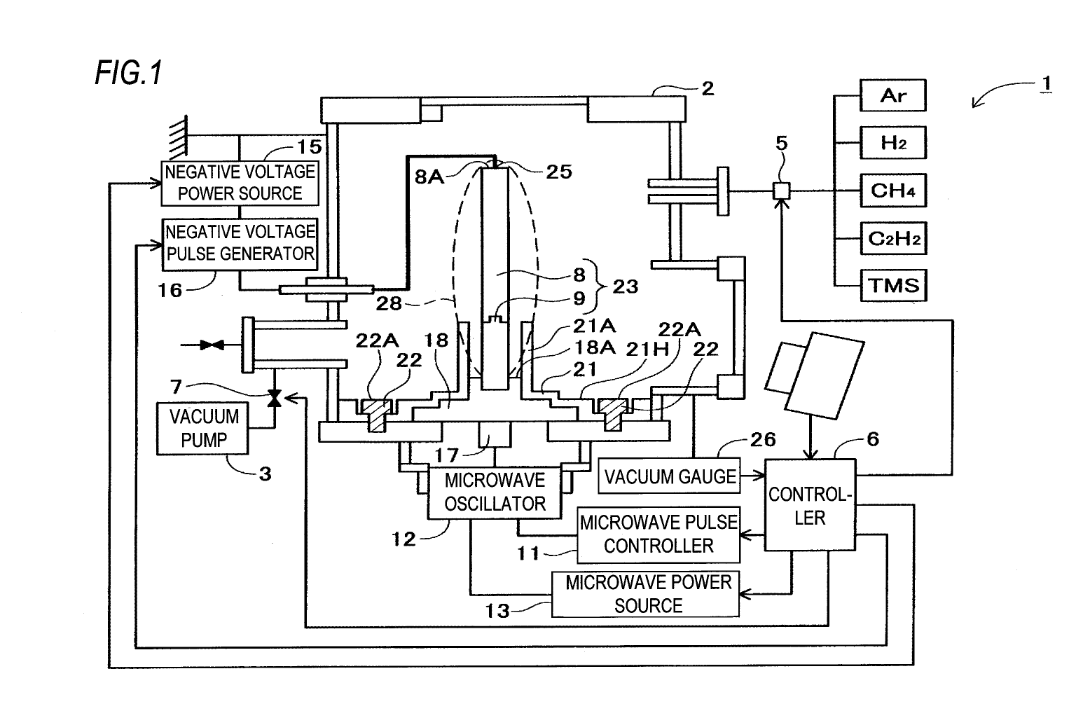

Hereinafter, an illustrative embodiment in which the film-forming device of the present invention is implemented will be described in detail with reference to the drawings. First, a schematic configuration of a film-forming device 1 according to the illustrative embodiment will be described with reference to FIGS. 1 to 3.

As shown in FIGS. 1 to 3, the film-forming device 1 of the illustrative embodiment includes a treatment chamber 2, a vacuum pump 3, a gas supplying unit 5, a controller 6 and the like. The treatment chamber 2 is made of metal such as stainless steel and has an airtight structure. The vacuum pump 3 is a pump capable of evacuating an inside of the treatment chamber 2 through a pressure adjusting valve 7. In the treatment chamber 2, a conductive workpiece material 8, which is a film formation target, is held by a conductive holder 9 made of stainless steel and the like.

The workpiece material 8 is not particularly limited inasmuch as it has conductivity. In the illustrative embodiment, low-temperature tempered steel is used. Here, the low-temperature tempered steel is a material such as JIS G4051 (Carbon steel for machine structural use), G4401 (Carbon tool steel), G44-4 (Steel for alloy tool) or maraging steel material. As the workpiece material, a material of which ceramic or resin is covered with a conductive material may be used, in addition to the low-temperature tempered steel.

The gas supplying unit 5 supplies a source gas for film formation and an inert gas into the treatment chamber 2. Specifically, the inert gas such as He, Ne, Ar, Kr, Xe and the like and the source gas such as CH₄, CH₂, C₂H₂, TMS (tetramethylsilane) and the like are supplied. The illustrative embodiment will be described as a DLC film is formed on the workpiece material 8 by the source gas of CH₄, C₂H₂ and TMS.

Also, flow rates and pressures of the source gas and inert gas supplied from the gas supplying unit 5 may be controlled by the controller 6 or may be controlled by an operator. Also, the source gas may be a gas including a compound having a CH bonding such as alkine, alkene, alkane, aromatic compound and the like or a compound including carbons. Also, H₂ may be contained in the source gas.

Plasma is generated so as to form a DLC film on the workpiece material 8 held in the treatment chamber 2. The plasma is generated by a microwave pulse controller 11, a microwave oscillator 12, a microwave power source 13, a negative voltage power source 15 and a negative voltage pulse generator 16. In the illustrative embodiment, it will be described that the surface wave excitation plasma is generated by a method disclosed in Japanese Patent Application Publication No. 2004-47207A (hereinafter, referred to as microwave sheath-Voltage combination Plasma (MVP) method). In the below, the MVP method will be described.

The microwave pulse controller 11 oscillates a pulse signal and to supply the oscillated pulse signal to the microwave oscillator 12, in response to an instruction of the controller 6. The microwave oscillator 12 generates microwave pulses, in response to the pulse signal from the microwave pulse controller 11. The microwave power source 13 feeds power to the microwave oscillator 12, which oscillates microwaves of 2.45 GHz with an instructed output, in response to an instruction of the controller 6. That is, the microwave oscillator 12 supplies the microwaves of 2.45 GHz, as microwave pulses having a pulse shape, in response to the pulse signal from the microwave pulse controller 11.

The microwave pulses having a pulse shape are supplied from the microwave oscillator 12 to the holder 9 and a treatment surface of the workpiece material 8 via an isolator and a matching box, which are not shown, a waveguide 17 and a microwave transmitting window 18 made of a dielectric substance and the like through which the microwaves penetrate, such as quartz. The isolator is provided so as to suppress reflected waves of the microwaves from returning to the microwave oscillator 12. The matching box is provided to adjust impedances before and after the matching box so as to minimize the reflected waves of the microwaves, based on the reflection energy of the microwaves reflected in the waveguide 17, which is detected at a reflection energy detection unit.

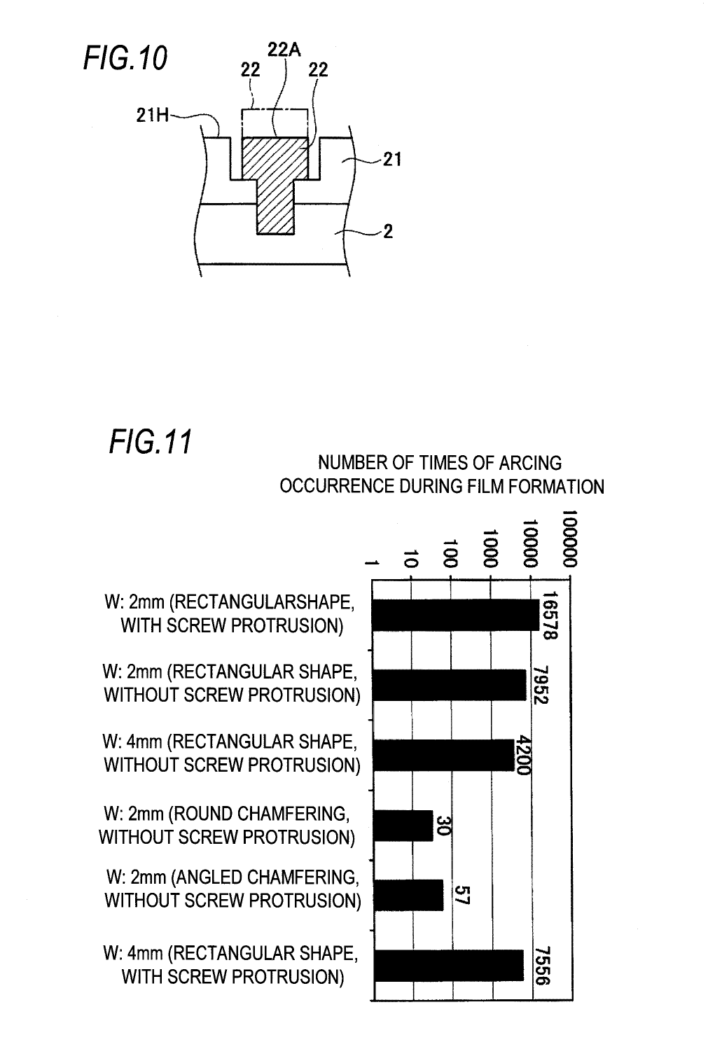

An outer peripheral surface of the microwave transmitting window 18 except for an upper end surface, i.e., an outer peripheral surface except for a microwave transmitting surface 18A is covered with a side electrode 21 made of metal such as stainless steel. The side electrode 21 is attached to inside the treatment chamber 2 by two screws 22, and is electrically connected to the treatment chamber 2. The side electrode 21 may be attached by an attachment member such as at least one screw. As shown in FIG. 10, an upper end surface 22A of each screw 22 is provided so that it is substantially flush with an upper end surface 21H of the side electrode 21 or is slightly lower than the upper end surface 21H of the side electrode 21, i.e., so that it does not protrude from the surface of the side electrode 21.

As shown in FIG. 1, the side electrode 21 is formed with a cylindrical surrounding wall 21A protruding from a part contacting an outer periphery of the microwave transmitting surface 18A into the treatment chamber 2 over an entire circumference of the side electrode 21. The surrounding wall 21A is formed over the entire circumference of the microwave transmitting surface 18A so that it surrounds a central conductor 23, which has the holder 9 and the workpiece material 8, at an inside thereof. That is, the surrounding wall 21A is made of metal such as stainless steel. Also, each screw 22 is arranged at an outermore side than the surrounding wall 21A.

In the meantime, only the cylindrical surrounding wall 21A may be configured by a separate component of ceramic or resin, a conductive metal material may be coated on at least an inner peripheral surface thereof, and the surrounding wall 21A may be fixed to an upper side of the side electrode 21 made of metal such as stainless steel so that a base end portion thereof is contacted to the outer periphery of the microwave transmitting surface 18A. The base end portion is a part corresponding to a lower limit position of a height H of the surrounding wall 21A (refer to FIG. 3).

Since the inner peripheral surface of the surrounding wall 21A is made of metal and a negative bias voltage is not applied to the inner peripheral surface, it is possible to concentrate the plasma on the central conductor 23 arranged at an inner side of the surrounding wall 21A, so that it is possible to reduce arcing occurrence due to the electric field concentration. Further, even when the inner peripheral surface of the surrounding wall 21A is equipotential with the treatment chamber 2, it is possible to concentrate the plasma on the central conductor 23 arranged at the inner side of the surrounding wall 21A, so that it is possible to reduce the arcing occurrence due to the electric field concentration.

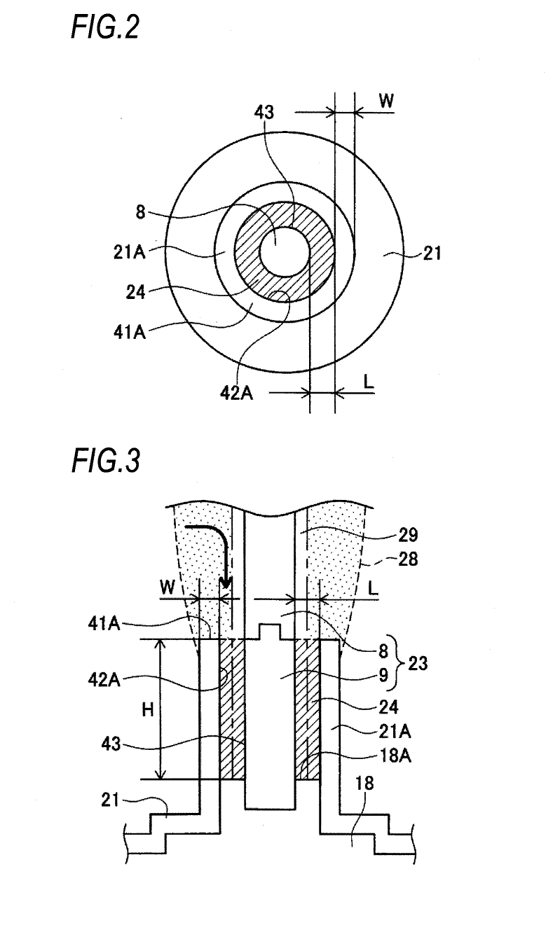

As shown in FIGS. 2 and 3, the surrounding wall 21A forms a surrounding space 24 having a height H from the microwave transmitting surface 18A to a tip portion 41A of the surrounding wall 21A and a distance L from an inner peripheral surface 42A of the surrounding wall 21A to an outer peripheral surface 43 of the central conductor 23, at the inner side thereof. Therefore, the surrounding space 24 has a substantially cylindrical shape in which a side facing the microwave transmitting surface 18A is closed and an inner side facing the treatment chamber 2 is opened. For this reason, the microwaves are propagated to the microwave transmitting surface 18A by the microwave pulses supplied to the microwave transmitting window 18, and the plasma is generated in the surrounding space 24. In the meantime, when the inner peripheral surface of the surrounding wall 21A is uneven, the shortest distance from the inner peripheral surface of the surrounding wall 21A to the outer peripheral surface 43 of the central conductor 23 is set as the distance L.

When the negative bias voltage pulses are applied to the central conductor 23 through a negative voltage electrode 25 (which will be described later), a sheath layer 29 is formed along a surface of the central conductor 23, as shown in FIG. 3. The negative bias voltage pulse may be the same as or later than an applying timing of the microwave pulse. Therefore, the surrounding space 24 of which a side facing the microwave transmitting surface 18A is closed is formed to surround the expanded sheath layer 29 at the inner side of the surrounding wall 21A. Also, the distance L from the inner peripheral surface 42A of the surrounding wall 21A to the outer peripheral surface 43 of the central conductor 23 is formed to be shorter than the height H from the microwave transmitting surface 18A to the tip portion 41A of the surrounding wall 21A.

Thereby, the surrounding space 24 surrounding the central conductor 23 formed at the inner side of the surrounding wall 21A can be formed to be narrow in a sheath thickness direction of the sheath layer 29 and to be high in a propagation direction of the microwaves. Therefore, after a film is formed on the central conductor 23 by the source gas supplied into the surrounding space 24, it is possible to reduce the additional supply of the source gas into the surrounding space 24, so that it is possible to reduce an attachment amount of the film component to the microwave transmitting surface 18A.

As shown in FIG. 1, a part of the workpiece material 8 opposite to the holder 9 is arranged to protrude towards an inside of the treatment chamber 2 with respect to the microwave transmitting window 18. A tip portion 8A of the part of the workpiece material 8 opposite to the holder 9 is electrically connected with the negative voltage electrode 25 for applying a negative bias voltage pulse.

The negative voltage power source 15 supplies a negative bias voltage to the negative voltage pulse generator 16, in response to an instruction of the controller 6. The negative voltage pulse generator 16 processes the negative bias voltage supplied from the negative voltage power source 15 to be the pulse. The pulsing processing is processing in which the negative voltage pulse generator 16 controls a magnitude, a period and a duty ratio of the negative bias voltage pulse, in response to an instruction of the controller 6. The negative bias voltage pulse, which is a negative bias voltage having a pulse shape conforming to the duty ratio, is applied to the workpiece material 8 held in the treatment chamber 2 through the negative voltage electrode 25.

That is, even when the workpiece material 8 is a metal-based material or a material of which ceramic or resin is covered with a conductive metal material, the negative bias voltage pulse is applied to at least the entire treatment surface of the workpiece material 8. Also, the negative bias voltage pulse is applied to the entire surface of the holder 9 through the workpiece material 8.

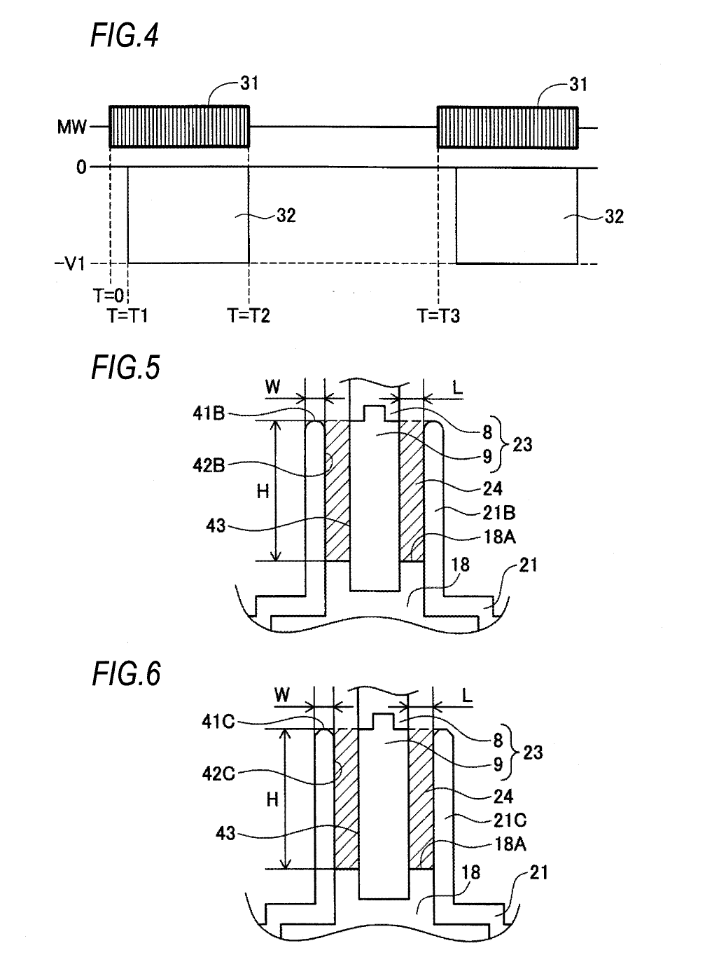

As shown in FIG. 4, the generated microwave pulses and at least a part of the negative bias voltage pulses are controlled to be applied at the same time, so that surface wave excitation plasma 28 is generated, as shown in FIG. 1. The microwave may have a frequency of 0.3 GHz to 50 GHz, without being limited to 2.45 GHz. The negative voltage power source 15 and the negative voltage pulse generator 16 are examples of the negative voltage applying unit of the present invention.

The microwave pulse controller 11, the microwave oscillator 12, the microwave power source 13, the isolator (not shown), the matching box, and the waveguide 17 are examples of the microwave supplying unit of the present invention. In the meantime, the film-forming device 1 has the negative voltage power source 15 and the negative voltage pulse generator 16. However, the film-forming device may have a constant voltage power source and a constant voltage pulse generator. Also, the film-forming device may have a negative voltage generator applies a continuous negative bias voltage, not the negative bias voltage having a pulse shape, instead of the negative voltage pulse generator 16.

As shown in FIG. 1, the controller 6 has a CPU, a RAM, a ROM, a hard disk drive (hereinafter, referred to as ‘HDD’), a timer and the like, which are not shown, is configured by a computer and controls the entire film-forming device 1. The ROM and the HDD of the controller 6 are non-volatile storage devices and store therein information indicating applying timings of the microwave pulse and the negative bias voltage pulse shown in FIG. 4.

The controller 6 outputs control signals to the negative voltage power source 15 and the microwave power source 13, thereby controlling an applying power of the microwave pulse and an applying voltage of the negative voltage pulse. The controller 6 outputs control signals to the negative voltage pulse generator 16 and the microwave pulse controller 11, thereby controlling an applying timing and a supply voltage of the negative bias voltage pulse having a pulse shape, and a supply timing and a supply power of the microwave pulse to be generated from the microwave oscillator 12.

Also, the controller 6 outputs a flow rate control signal to the gas supplying unit 5, thereby controlling the supply of the source gas and inert gas. The controller 6 outputs a control signal to the pressure adjusting valve 7 based on a pressure signal, which is input from a vacuum gauge 26 attached to the treatment chamber 2 and indicates a pressure in the treatment chamber 2, thereby controlling the pressure in the treatment chamber 2.

[Description of Surface Wave Excitation Plasma]

In general, when generating the surface wave excitation plasma, the microwaves are supplied along a boundary between plasma having an electron (ion) density of a predetermined level or higher and a dielectric substance contacting the plasma. The supplied microwaves propagate as the surface waves at a state where the energy of electromagnetic waves is concentrated at the boundary. As a result, the plasma contacting the boundary is excited by the surface waves with the high energy density and is further amplified. Thereby, the high density plasma is generated and kept. When the dielectric substance is changed to a conductive material, the conductive material does not function as a waveguide of the surface waves and it is not possible to propagate the preferred surface waves and to excite the plasma.

In the meantime, a charged particle layer having an essentially single polarity, a so-called sheath layer is formed in the vicinity of a surface of an object contacting the plasma. When the object is the conductive workpiece material 8 to which the negative bias voltage is applied, the sheath layer is a layer of which an electron density is low, i.e., a layer that is positively polar and has a specific dielectric constant (∈ is approximately equal to 1) in a frequency band of the microwaves. For this reason, it is possible to increase a sheath thickness of the sheath layer by making an absolute value of the negative bias voltage to be applied higher than an absolute value of −100V, for example. That is, the sheath layer expands. The sheath layer functions as a dielectric substance propagating the surface waves to a boundary between the plasma and the object contacting the plasma.

Therefore, as shown in FIG. 3, when the microwaves are supplied from the microwave transmitting surface 18A arranged to be close to one end of the holder 9 holding the workpiece material 8 and the negative bias voltage is applied to the workpiece material 8 and the holder 9 through the negative voltage electrode 25, the microwaves propagate as the surface waves along the boundary between the sheath layer and the plasma. As a result, the high density excitation plasma based on the surface waves is generated along the surfaces of the workpiece material 8 and holder 9. The high density excitation plasma is the surface wave excitation plasma 45.

The electron density of the high density plasma, which is generated by the surface wave excitation in the vicinity of the surface of the workpiece material 8, is 10¹¹ to 10¹² cm⁻³. When a DLC film is formed by a plasma CVD using the MVP method, the film formation speed of 3 to 30 (nanometer/sec) is obtained, which is higher by single-digit or double-digits, as compared to a case where the DLC film-forming processing is performed by the plasma CVD of the usual negative bias voltage energy. As a result, the film formation time of the plasma CVD by the MVP method is 1/10 to 1/100 of the film formation time of the usual plasma CVD.

Here, an example of the applying timings of the microwave pulse and the negative bias voltage pulse stored in the ROM or HDD of the controller 6 will be described with reference to FIG. 4. In FIG. 4, the negative bias voltage is denoted as V.

As shown in FIG. 4, a period of a microwave pulse 31 is T3 (second). A supply time per one pulse of a microwave pulse 31 is T2 (second). In the illustrative embodiment, T2 is set to be about a half of T3. Also, a period of a negative bias voltage pulse 32 is the same as the period of the microwave pulse 31, i.e., T3 (second). For example, the periods of the microwave pulse 31 and the negative bias voltage pulse 32 are all T3=2 (milliseconds).

An applying time of the negative bias voltage pulse 32 is (T2−T1) (second), and is set to a time of 90% or greater of the supply time T2 (second) of the microwave pulse 31. An applying timing of the negative bias voltage pulse 52 is set to be delayed by T1 (second), as compared to a supply start timing of the microwave pulse 51. That is, the negative bias voltage pulse 32 is applied after the microwave pulse 51 rises and the power is stable. For example, the delay time T1=8 (microseconds).

Here, as shown in FIG. 5, a surrounding wall 21B may be formed, instead of the surrounding wall 21A. The surrounding wall 21B has the substantially shape as the surrounding wall 21A. However, a tip portion 41B thereof is roundly chamfered. The surrounding wall 21B forms the surrounding space 24 having a distance L from an inner peripheral surface 42B of the surrounding wall 21B to the outer peripheral surface 43 of the central conductor 23 within a range of a height H from the microwave transmitting surface 18A to the tip portion 41B of the surrounding wall 21B, at the inner side thereof. Therefore, the surrounding space 24 has a substantially cylindrical shape of which a side facing the microwave transmitting surface 18A is closed and an inner side facing the treatment chamber 2 is opened. The distance L is formed to be shorter than the height H. Due to the round chamfering, it is possible to further suppress the electric field concentration, as compared to the surrounding electrode having no round chamfering, so that the number of times of arcing occurrence decreases.

Also, as shown in FIG. 6, a surrounding wall 21C may be formed, instead of the surrounding wall 21A. The surrounding wall 21C has the substantially shape as the surrounding wall 21A. However, a tip portion 41C thereof is angle-chamfered. The surrounding wall 21C is configured to form the surrounding space 24 having a distance L from an inner peripheral surface 42C of the surrounding wall 21C to the outer peripheral surface 43 of the central conductor 23 within a range of a height H from the microwave transmitting surface 18A to the tip portion 41C of the surrounding wall 21B, at the inner side thereof. Therefore, the surrounding space 24 has a substantially cylindrical shape of which a side facing the microwave transmitting surface 18A is closed and an inner side facing the treatment chamber 2 is opened. The distance L is formed to be shorter than the height H. Due to the angled chamfering, as compared to the surrounding electrode having no angled chamfering, the number of corners increases, so that the electric field is more difficult to concentrate. As a result, since it is possible to suppress the electric field concentration, the number of times of arcing occurrence decreases.

[Measurement of Number of Continuous Usable Times of Microwave Transmitting Window 18]

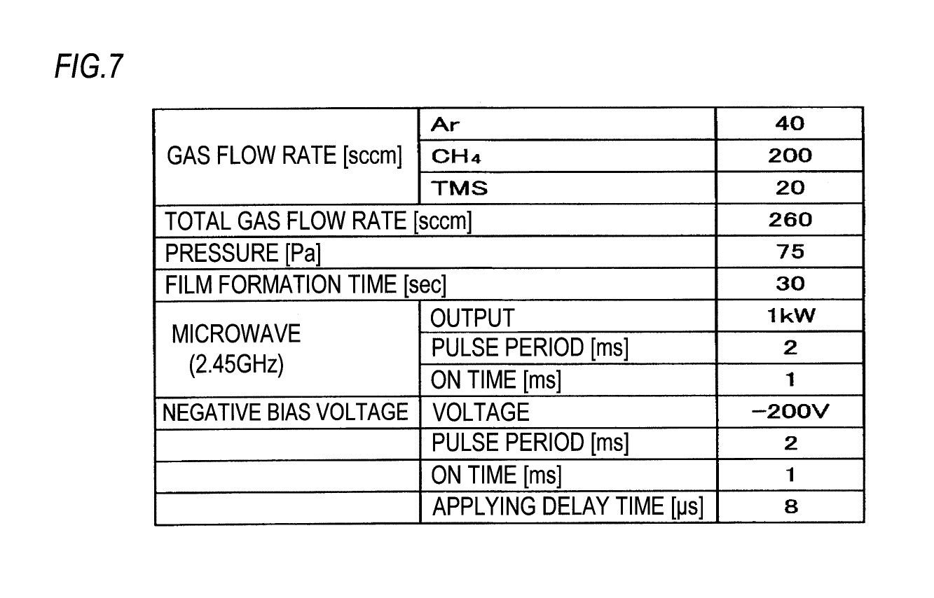

Subsequently, an example of a test result where the number of continuous usable times was measured until the microwave transmitting window 18 is required to be replaced in the film-forming device 1 configured as described above will be described with reference to FIGS. 7 to 9. The number of continuous usable times of the microwave transmitting window 18 was measured with changing the height H of the surrounding wall 21A from the microwave transmitting surface 18A and the distance L of the surrounding wall 21A from the inner peripheral surface 42A to the outer peripheral surface 43 of the central conductor 23. In the meantime, a thickness W of the surrounding wall 21A shown in FIGS. 2 and 3 was set to 2 mm. The tip portion 41A of the surrounding wall 21A facing the inside of the treatment chamber 2 was not chamfered, and a section of the tip portion was a rectangular shape.

First, the film formation processing and the film formation conditions will be described with reference to FIGS. 1 and 7. When starting the DLC film formation, the controller 6 activates the vacuum pump 3 and waits until a predetermined degree of vacuum (for example, 1 Pa) is reached, based on the pressure signal input from the vacuum gauge 26. Then, the controller 6 supplies the inert gas and the source gas into the treatment chamber 2 through the gas supplying unit 5. Also, the controller 6 evacuates the inert gas and the source gas in the treatment chamber 2 at constant flow rates through the pressure adjusting valve 7 so that the inside of the treatment chamber 2 reaches a predetermined pressure, based on the pressure signal input from the vacuum gauge 26.

As shown in FIG. 7, the controller 6 supplied Ar as the inert gas and CH₄ and TMS as the source gas into the treatment chamber 2 at the flow rates of 40 sccm, 200 sccm and 20 sccm, respectively. That is, the gases of 260 sccm were supplied to the treatment chamber 2. The controller 6 controlled the pressure of the treatment chamber 2 to 75 Pa.

Subsequently, the controller 6 instructs a microwave supply power value to the microwave power source 13 and transmits on-and-off signals of the microwave pulses 31 to the microwave pulse controller 11 with a predetermined period. As shown in FIG. 7, for the 2.45 GHz microwave, 1 kW power as the power, 2 milliseconds as the pulse period of the microwave pulse, and 1 millisecond as the applying time of the microwave pulse were set, respectively.

At the same time, the controller 6 instructs a negative bias voltage value to the negative voltage power source 15. Also, the controller 6 transmits on-and-off signals of the negative bias voltage pulses 32 to the negative voltage pulse generator 16 with a predetermined period. As shown in FIG. 7, for the negative bias voltage pulse, −200V as the voltage, 2 milliseconds as the pulse period, and 1 millisecond as the applying time of the negative bias voltage pulse were set, respectively. The supply timing of the microwave pulse and the applying timing of the negative bias voltage pulse were set so that the microwave pulse precedes merely by 8 microseconds. The offset of the applying timings is denoted as time T1 in FIG. 4.

Then, the controller 6 applied the microwave pulses and the negative bias voltage pulses at the applying timings shown in FIG. 4, set the film formation time to 30 seconds and performed the film formation. At the early stage of the DLC film formation, the plasma was generated and the source gas was consumed in the surrounding space 24. Thereafter, since the source gas supplied into the surrounding space 24 at the early stage is consumed, the additional supply of the source gas into the surrounding space 24 is reduced, so that it is possible to suppress the generation of the plasma of the source gas.

As a result, it is possible to reduce an amount of the DLC film component to be attached to the microwave transmitting surface 18A. Also, the DLC film attached to the microwave transmitting surface 18A is ion-cleaned by the inert gas transformed into the plasma in the surrounding space 24, and the number of usable times of the microwave transmitting window 18 can be considerably increased, so that it is possible to improve the productivity.

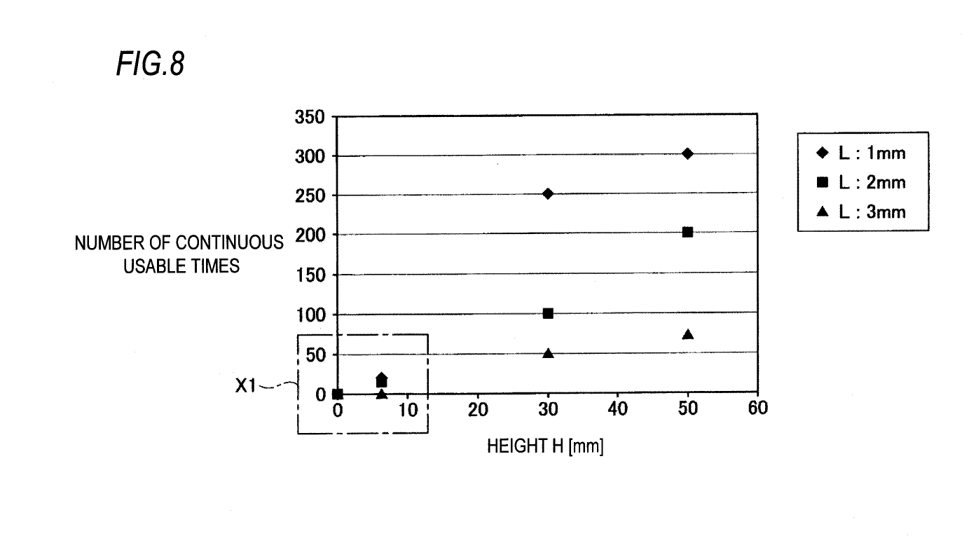

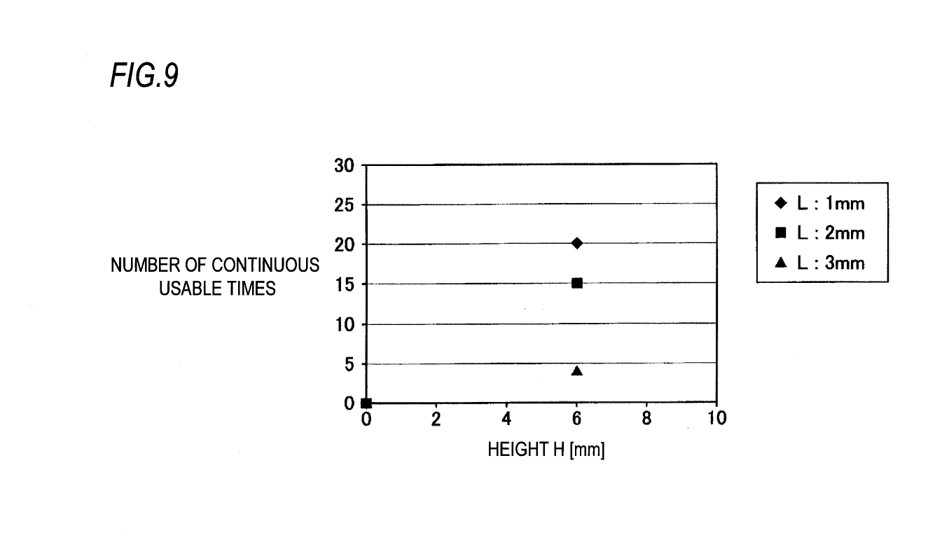

Subsequently, an example of a test result where the number of continuous usable times of the microwave transmitting window 18 was measured will be described with reference to FIGS. 8 and 9. Meanwhile, in FIG. 8, the number of continuous usable times ‘0’ indicates that the microwave transmitting window 18 could be used only once.

As shown in FIGS. 8 and 9, the distance L from the inner peripheral surface 42A of the surrounding wall 21A to the outer peripheral surface 43 of the central conductor 23 was set to 3 mm, and the height H from the microwave transmitting surface 18A to the tip portion 41A of the surrounding wall 21A was sequentially changed to 6 mm, 30 mm and 50 mm. In this case, the number of continuous usable times of the microwave transmitting window 18 was 4 times, 50 times and 75 times, respectively.

Then, the distance L from the inner peripheral surface 42A of the surrounding wall 21A to the outer peripheral surface 43 of the central conductor 23 was set to 2 mm, and the height H from the microwave transmitting surface 18A to the tip portion 41A of the surrounding wall 21A was sequentially changed to 6 mm, 30 mm and 50 mm. In this case, the number of continuous usable times of the microwave transmitting window 18 was 15 times, 100 times and 200 times, respectively. Also, the distance L from the inner peripheral surface 42A of the surrounding wall 21A to the outer peripheral surface 43 of the central conductor 23 was set to 1 mm, and the height H from the microwave transmitting surface 18A to the tip portion 41A of the surrounding wall 21A was sequentially changed to 6 mm, 30 mm and 50 mm. In this case, the number of continuous usable times of the microwave transmitting window 18 was 20 times, 250 times and 300 times, respectively.

Therefore, the distance L from the inner peripheral surface 42A of the surrounding wall 21A to the outer peripheral surface 43 of the central conductor 23 is set to 2 mm or less, and the height H from the microwave transmitting surface 18A to the tip portion 41A of the surrounding wall 21A is set to 30 mm or greater. Thereby, it is possible to securely suppress the replacement of the source gas in the vicinity of the microwave transmitting surface 18A in the surrounding space 24 formed at the inner side of the surrounding wall 21A, thereby reducing the attachment amount of the film component to the microwave transmitting surface 18A.

Further, the DLC film attached to the microwave transmitting surface 18A is ion-cleaned by the inert gas transformed into the plasma in the surrounding space 24, so that it is possible to increase the number of usable times of the microwave transmitting window 18 to 100 times or greater. For example, when it takes about 2 minutes to perform the one DLC film formation processing, it is possible to continuously use the microwave transmitting window 18 for 2×100=200 (minutes), i.e., about 3 hours and 20 minutes. As a result, when it is assumed that the film-forming device 1 operates for 7 hours per one day, the microwave transmitting window 18 has only to be replaced two times per one day, so that it is possible to improve the productivity.

[Measurement of Number of Times of Arcing Occurrence During Film Formation]

Subsequently, an example of a test result where the number of times of arcing occurrence was measured during the DLC film formation in the film-forming device 1 configured as described above will be described with reference to FIGS. 3, 5, 6, 10 and 11. The number of times of arcing occurrence during the DLC film formation was measured by combinations of shapes of the respective tip portions 41A to 41C of the surrounding walls 21A to 21C, the thicknesses W of the respective surrounding walls 21A to 21C in a direction perpendicular to the propagation direction of the microwaves in the sheath layer 29, and presence or absence of each screw 22 protruding from the surface of the side electrode 21.

In the meantime, the DLC film formation processing and the film formation conditions are substantially the same as the film formation processing during which the number of continuous usable times of the microwave transmitting window 18 was measured and the film formation conditions shown in FIG. 7. However, the film formation time was set to 50 seconds. Also, the height H from the microwave transmitting surface 18A to each of the tip portions 41A to 41C of the surrounding walls 21A to 21C was set to 30 mm. Also, the distance L from each of the inner peripheral surfaces 42A to 42C of the surrounding walls 21A to 21C to the outer peripheral surface 43 of the central conductor 23 was set to 2 mm.

The test condition in a case where the number of times of arcing occurrence was ‘16578’ times (refer to the first from left in FIG. 11) is that the tip portion 41A of the surrounding wall 21A had the rectangular section as shown in FIG. 3, i.e., the tip portion 41A was not chamfered. The thickness W of the surrounding wall 21A was set to 2 mm. Each screw 22 was made to protrude from the surface, i.e., the upper end surface 21H of the side electrode 21 by about 5 mm, as shown with the dashed-dotted line in FIG. 10.

The test condition in a case where the number of times of arcing occurrence was ‘7952’ times (refer to the second from left in FIG. 11) is that the tip portion 41A of the surrounding wall 21A had the rectangular section as shown in FIG. 3, i.e., the tip portion 41A was not chamfered. The thickness W of the surrounding wall 21A was set to 2 mm. Each screw 22 was made to be flush with the surface of the side electrode 21, i.e., was made not to protrude from the upper end surface 21H of the side electrode 21, as shown with the solid line in FIG. 10.

The test condition in a case where the number of times of arcing occurrence was ‘4200’ times (refer to the third from left in FIG. 11) is that the tip portion 41A of the surrounding wall 21A had the rectangular section as shown in FIG. 3, i.e., the tip portion 41A was not chamfered. The thickness W of the surrounding wall 21A was set to 4 mm. Each screw 22 was made to be flush with the surface of the side electrode 21, i.e., was made not to protrude from the upper end surface 21H of the side electrode 21, as shown with the solid line in FIG. 10.

The test condition in a case where the number of times of arcing occurrence was ‘30’ times (refer to the fourth from left in FIG. 11) is that the surrounding wall 21B was provided instead of the surrounding wall 21A. As shown in FIG. 5, the tip portion 41B of the surrounding wall 21B was roundly chamfered. In the round chamfering, a radius of curvature was about 1 mm. In the meantime, the round chamfering is preferably performed to make a radius of curvature of 1 mm or greater. The thickness W of the surrounding wall 21B was set to 2 mm. Each screw 22 was made to be flush with the surface of the side electrode 21, i.e., was made not to protrude from the upper end surface 21H of the side electrode 21, as shown with the solid line in FIG. 10.

The test condition in a case where the number of times of arcing occurrence was ‘57’ times (refer to the fifth from left in FIG. 11) is that the surrounding wall 21C was provided instead of the surrounding wall 21A. As shown in FIG. 6, the tip portion 41C of the surrounding wall 21C was made to have an angled chamfering of about 1 mm. In the meantime, the angled chamfering is preferably performed to make an angled chamfering of about 1 mm or greater. The thickness W of the surrounding wall 21B was set to 2 mm. Each screw 22 was made to be flush with the surface of the side electrode 21, i.e., was made not to protrude from the upper end surface 21H of the side electrode 21, as shown with the solid line in FIG. 10.

The test condition in a case where the number of times of arcing occurrence was ‘7556’ times (refer to the sixth from left in FIG. 11) is that the tip portion 41A of the surrounding wall 21A had the rectangular section as shown in FIG. 3, i.e., the tip portion 41A was not chamfered. The thickness W of the surrounding wall 21A was set to 4 mm. Each screw 22 was made to protrude from the upper end surface 21H of the side electrode 21 by about 5 mm, as shown with the dashed-dotted line in FIG. 10.

Here, when the film formation time is set to 50 seconds, if the duty ratio of the applying time with respect to the period (2 milliseconds) of the microwave pulse is set to an average 80%, the actual film formation time is 40 seconds. Also, in order to obtain the film hardness uniformity of 96% or greater, the possible applying stop time of the negative bias voltage pulse due to the arcing occurrence is 1.4 (seconds) (=40 (seconds)×(1-0.96)−8 (microseconds)×50 (seconds)÷2 (milliseconds)). When the applying of the negative bias voltage pulse is stopped for 150 microseconds whenever the arcing occurs, the permitted number of times of arcing occurrence is 9333 times (=1.4÷0.00015).

Therefore, the thickness W of the surrounding wall 21A in the direction perpendicular to the propagation direction of the microwaves in the sheath layer 29 is made to be 4 mm or greater. Thereby, even when each screw 22 protrudes from the upper end surface 21H of the side electrode 21, it is possible to suppress the voltage from concentrating on the tip portion of the surrounding wall 21A. Thereby, it is possible to limit the number of times of arcing occurrence during the film formation to the preset number of times of arcing occurrence or less, for example, 9333 times or less. Therefore, it is possible to stabilize the plasma discharge, thereby forming a desired DLC film having uniform film characteristics on the surface of the workpiece material 8.

In the meantime, the thickness W of the surrounding wall 21A in the direction perpendicular to the propagation direction of the microwaves in the sheath layer 29 may be set to 2 mm. Then, the tip portion 41A of the surrounding wall 21A may be made to extend in a ring shape over an entire circumference in a radially outer direction so that only the tip portion of the surrounding wall 21A opposite to the microwave transmitting surface 18A has the thickness W of 4 mm or greater. Thereby, even when each screw 22 protrudes from the upper end surface 21H of the side electrode 21, it is possible to suppress the voltage from concentrating on the tip portion of the surrounding wall 21A. Thereby, it is possible to limit the number of times of arcing occurrence during the film formation to the preset number of times of arcing occurrence or less, for example, 9333 times or less.

Also, each of the tip portions 41B, 41C of the surrounding walls 21B, 21C opposite to the microwave transmitting surface 18A is formed with the round chamfering or the angled chamfering over the entire circumference. Therefore, it is possible to securely suppress the voltage from concentrating on each of the tip portions 41B, 41C of the surrounding walls 21B, 21C. Thereby, it is possible to considerably reduce the number of times of arcing occurrence during the film formation to the preset number of times of arcing occurrence or less. Therefore, it is possible to stabilize the plasma discharge, thereby securely forming a desired DLC film having uniform film characteristics on the surface of the workpiece material 8.

Also, each screw 22 for attaching the side electrode 21 to the treatment chamber 2 is arranged at the outer side of each of the surrounding walls 21A to 21C and is provided not to protrude from the upper end surface 21H of the side electrode 21, so that it is possible to reduce the arcing occurrence due to the electric field concentration on each screw 22. Therefore, it is possible to stabilize the plasma discharge, thereby forming a desired DLC film having uniform film characteristics on the surface of the workpiece material 8.

Further, each of the surrounding walls 21A to 21C is electrically connected to the treatment chamber 2 having the microwave transmitting window 18 through each screw 22. Thereby, it is possible to reduce the arcing occurrence due to the electric field concentration on each of the tip portions 41A to 41C of the surrounding walls 21A to 21C. Therefore, it is possible to stabilize the plasma discharge, thereby forming a desired DLC film having uniform film characteristics on the surface of the workpiece material 8.

According to the technology disclosed in Patent Document 1, during the film formation on the surface of the workpiece material, the film is also attached to the microwave transmitting surface of the quartz window facing the workpiece material. The film attached to the microwave transmitting surface is charged by the plasma, thereby causing the arcing. When the arcing occurs, it is necessary to interrupt the supply of the negative bias voltage for a predetermined time period. As a result, the plasma discharge is unstable, so that the film characteristics of the film formed on the surface of the workpiece material are not uniform.

In contrast, according to the film-forming device 1 of the illustrative embodiment, the microwave transmitting surface 18A for making the microwaves propagate to the expanded sheath layer 29 is surrounded by any one of the surrounding walls 21A to 21C protruding in the propagation direction of the microwaves. For this reason, the surrounding space 24 surrounding the expanded sheath layer 29 and closed at the side facing the microwave transmitting surface 18A is formed at the inner side of one of the surrounding walls 21A to 21C.

Thereby, after the film is formed on the central conductor 23 by the source gas supplied into the surrounding space 24, it is possible to reduce the additional supply of the source gas into the surrounding space 24. Therefore, it is possible to reduce the attachment amount of the film component to the microwave transmitting surface 18A, thereby reducing the arcing occurrence. As a result, it is possible to prolong the lifetime of the microwave transmitting window 18, thereby improving the productivity.

In the meantime, when the metallic film is formed on the workpiece material 8, a component of the metallic film may be attached to the microwave transmitting surface 18A. Since the attached component reflects the microwaves being supplied, the propagation efficiency of the microwaves in the sheath layer 29 is lowered, so that the film formation speed is lowered. However, according to the illustrative embodiment, even though the metallic film is formed on the workpiece material 8, after the source gas including a metal component is supplied into the surrounding space 24 and the metallic film is formed, it is possible to reduce the additional supply of the source gas into the surrounding space 24 by one of the surrounding walls 21A to 21C. Therefore, the attachment amount of the film component to the microwave transmitting surface 18A is reduced to decrease the reflection of the microwaves due to the attached metallic film, so that it is possible to reduce the lowering of the film formation speed. As a result, it is possible to improve the productivity.

1. A film-forming device comprising:
a microwave supplying unit, which supplies microwaves for generating plasma along a treatment surface of a central conductor comprising at least a conductive workpiece material;
a negative voltage applying unit, which applies to the workpiece material a negative bias voltage for expanding a sheath layer along the treatment surface of the workpiece material;
a microwave transmitting window, which makes the microwave, which is supplied by the microwave supplying unit, propagate to the expanded sheath layer through a microwave transmitting surface thereof, and
a surrounding wall, which surrounds the microwave transmitting surface of the microwave transmitting window and protrudes beyond the microwave transmitting surface in a propagation direction in which the microwaves propagate.

2. The film-forming device according to claim 1,
wherein a distance from an inner peripheral surface of the surrounding wall to an outer peripheral surface of the central conductor arranged at an inner side of the surrounding wall is formed to be shorter than a height from the microwave transmitting surface to a tip of the surrounding wall opposite to the microwave transmitting surface.

3. The film-forming device according to claim 2,
wherein the distance is formed to be 2 mm or less and the height is formed to be 30 mm or greater.

4. The film-forming device according to claim 1,
wherein a thickness of a tip portion of the surrounding wall, which is opposite to the microwave transmitting surface, in a direction perpendicular to the propagation direction is formed to be 4 mm or greater.

5. The film-forming device according to claim 1,
wherein a tip portion of the surrounding wall, which is opposite to the microwave transmitting surface, is roundly chamfered.

6. The film-forming device according to claim 1,
wherein a tip portion of the surrounding wall, which is opposite to the microwave transmitting surface, is angle-chamfered.

7. The film-forming device according to claim 1, further comprising:
a support member, which supports the surrounding wall and the microwave transmitting window to a treatment chamber, and
an attachment member, which attaches the support member to the treatment chamber,
wherein the attachment member is arranged at an outer side of the surrounding wall and is provided not to protrude from a surface of the support member.

8. The film-forming device according to claim 1,
wherein an inner peripheral surface of the surrounding wall is made of metal.

9. The film-forming device according to claim 1,
wherein a tip portion of the surrounding wall, which is opposite to the microwave transmitting surface, is electrically connected to a treatment chamber having the microwave transmitting window.
